(19) United States
(12) Patent Application Publication
(10) Pub. No.: US 2026/0059858 A1
(43) Pub. Date: Feb. 26, 2026

(54) SEED STRUCTURES IN SEMICONDUCTOR DEVICES AND FABRICATION THEREOF

(71) Applicant: International Business Machines Corporation, Armonk, NY (US)

(72) Inventors: Fausto Martelli, Stockton Heath (GB); Teodor Krassimirov Todorov, Yorktown Heights, NY (US); Ching-Tzu Chen, Ossining, NY (US); Jed Pitera, Portola Valley, CA (US); Fabio Carta, Pleasantville, NY (US); Guy M. Cohen, Westchester, NY (US); Leonidas Ernesto Ocola, Wappingers Falls, NY (US); Benjamin Hardy Wunsch, Mt. Kisco, NY (US); Oleg Gluschenkov, Tannersville, NY (US)

(21) Appl. No.: 18/812,201

(22) Filed: Aug. 22, 2024

(51) Int. Cl. H01L 27/12; H01L 21/02; H01L 21/762; H01L 29/04; H01L 29/06

(52) U.S. Cl. CPC H10D 86/201; H01L 21/02667; H01L 21/76262; H10D 62/126; H10D 62/405

(57) ABSTRACT

A semiconductor device includes a plurality of seed structures disposed in a dielectric layer. The plurality of seed structures are spaced apart from each other. Respective ones of the plurality of seed structures have a tapered shape with a decreasing width from an upper surface of the dielectric layer, and include semiconductor crystalline material.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

At present, the performance of transistors is negatively affected by defects in a crystalline matrix and by randomly oriented crystalline patches in crystal semiconductor materials. A semiconductor substrate or its various epitaxially grown extensions can provide properly oriented seed crystal. However, transistors being formed at the back-end-of-line (BEOL) are not close enough to the semiconductor substrate to have access to substrate-driven crystal growth and the systematic orientation that such growth would produce.

A current approach to improve BEOL transistors includes bonding a thick single crystalline semiconducting layer to BEOL structures, which requires removal of excess semiconductor material. As a result, the current technique is limited to one extra bonded layer. Alternatively, there have been efforts to extend a crystalline seed from a substrate. However, there are limitations of length and size of such extended seeds.

### SUMMARY

Embodiments of the invention provide techniques for forming oriented crystal seed structures in semiconductor device dielectric layers.

In one embodiment, a semiconductor device includes a dielectric layer including at least one wedge-shaped seed structure. The at least one wedge-shaped seed structure includes semiconductor crystalline material.

In another embodiment, a semiconductor device includes a plurality of seed structures disposed in a dielectric layer. The plurality of seed structures are spaced apart from each other. Respective ones of the plurality of seed structures have a tapered shape with a decreasing width from an upper surface of the dielectric layer, and include semiconductor crystalline material.

In another embodiment, a semiconductor device includes a dielectric layer including a plurality of wedge-shaped grooves, wherein respective ones of the plurality of wedge-shaped grooves include respective ones of a plurality of seed structures disposed therein, the respective ones of the plurality of seed structures including a crystalline material. A plurality of transistors are disposed over the plurality of wedge-shaped grooves including the respective ones of the plurality of seed structures disposed therein.

In another embodiment, a semiconductor device includes a first seed structure disposed in a dielectric layer, a second seed structure disposed in the dielectric layer adjacent the first seed structure, a first field-effect transistor (FET) disposed on the first seed structure; and a second FET disposed on the second seed structure. The first seed structure and the second seed structure each have a tapered shape with a decreasing width in a direction away from the first FET and the second FET. The first seed structure and the second seed structure each include semiconductor crystalline material.

In another embodiment, a method for manufacturing a semiconductor device includes forming a plurality of wedge-shaped grooves in a dielectric layer, lining sides of respective ones of the plurality of wedge-shaped grooves with a crystalline film material having hexagonal symmetry, depositing amorphous semiconductor material in the respective ones of the plurality of wedge-shaped grooves, and melting and crystallizing the amorphous semiconductor material to form respective ones of a plurality seed structures in the respective ones of the plurality of wedge-shaped grooves. The respective ones of the plurality of seed structures include semiconductor crystalline material.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure illustrating a dielectric layer on a semiconductor substrate, according to an embodiment of the invention.

FIG. 2 depicts a cross-sectional view of a semiconductor structure following formation of wedge-shaped grooves, according to an embodiment of the invention.

FIG. 3 depicts a top view of the semiconductor structure of FIG. 2, according to an embodiment of the invention.

FIG. 4 depicts a cross-sectional view of the semiconductor structure from FIG. 2 including a notation for an enlarged view of the semiconductor structure in FIG. 5, according to an embodiment of the invention.

FIG. 5 depicts an enlarged cross-sectional view of a portion of the semiconductor structure of FIG. 4, according to an embodiment of the invention.

FIG. 6 depicts a cross-sectional view of an alternative semiconductor structure to the semiconductor structure in FIGS. 4 and 5, according to an embodiment of the invention.

FIG. 7 depicts a cross-sectional view of a semiconductor structure following deposition of hexagonal polycrystalline material, according to an embodiment of the invention.

FIG. 8 depicts a cross-sectional view of an enlarged portion of FIG. 7, according to an embodiment of the invention.

FIG. 9 depicts a representation of a surface of a groove wall, according to an embodiment of the invention.

FIG. 10 depicts a cross-sectional view of an alternative semiconductor structure following deposition of hexagonal two-dimensional (2D) material, according to an embodiment of the invention.

FIG. 11 depicts a cross-sectional view of an enlarged portion of FIG. 10, according to an embodiment of the invention.

FIG. 12 depicts a representation of a surface of a groove wall, according to an embodiment of the invention.

FIG. 13 depicts a representation of a surface of a groove wall, according to an embodiment of the invention.

FIG. 14 depicts a representation of a surface of a groove wall, according to an embodiment of the invention.

FIG. 15 depicts a cross-sectional view of a semiconductor structure following deposition of amorphous semiconductor material, according to an embodiment of the invention.

FIG. 16 depicts a cross-sectional view of a semiconductor structure following optional planarization of the amorphous semiconductor material, according to an embodiment of the invention.

FIG. 17 depicts a cross-sectional view of a semiconductor structure following laser annealing of amorphous semiconductor material, according to an embodiment of the invention.

FIG. 18 depicts a top view of the semiconductor structure of FIG. 17, according to an embodiment of the invention.

FIG. 19 depicts a cross-sectional view following optional planarization of the annealed semiconductor material if not performed prior to the annealing, according to an embodiment of the invention.

FIG. 20 depicts a top view of the semiconductor structure of FIG. 19, according to an embodiment of the invention.

FIG. 21 depicts a lattice arrangement of crystalline material in a (110) orientation, according to an embodiment of the invention.

FIG. 22 depicts a lattice arrangement of crystalline material in a (100) orientation, according to an embodiment of the invention.

FIG. 23 depicts a cross-sectional view of a semiconductor structure including defective edge zones, according to an embodiment of the invention.

FIG. 24 depicts a top view of the semiconductor structure of FIG. 23, according to an embodiment of the invention.

FIG. 25 depicts a cross-sectional view of a semiconductor structure following masking of non-defective seed material, according to an embodiment of the invention.

FIG. 26 depicts a top view of the semiconductor structure of FIG. 25, according to an embodiment of the invention.

FIG. 27 depicts a cross-sectional view of a semiconductor structure following removal of the defective edge zones, according to an embodiment of the invention.

FIG. 28 depicts a top view of the semiconductor structure of FIG. 27, according to an embodiment of the invention.

FIG. 29 depicts a cross-sectional view of a semiconductor structure following epitaxial growth of active areas from seed structures for planar FETs or FinFETs, according to an embodiment of the invention.

FIG. 30 depicts a top view of the semiconductor structure of FIG. 29, according to an embodiment of the invention.

FIG. 31 depicts a cross-sectional view of a semiconductor structure following patterning of active areas for FinFET formation, according to an embodiment of the invention.

FIG. 32 depicts a top view of the semiconductor structure of FIG. 32, according to an embodiment of the invention.

FIG. 33 depicts a cross-sectional view of a semiconductor structure following epitaxial growth of active areas from seed structures for nanosheet FETs, according to an embodiment of the invention.

FIG. 34 depicts a top view of the semiconductor structure of FIG. 33, according to an embodiment of the invention.

FIG. 35 depicts a cross-sectional view of a semiconductor structure following planar FET formation, according to an embodiment of the invention.

FIG. 36 depicts a top view of the semiconductor structure of FIG. 35, according to an embodiment of the invention.

FIG. 37 depicts a cross-sectional view of a semiconductor structure following FinFET formation, according to an embodiment of the invention.

FIG. 38 depicts a top view of the semiconductor structure of FIG. 37, according to an embodiment of the invention.

FIG. 39 depicts a cross-sectional view of a semiconductor structure following nanosheet FET formation, according to an embodiment of the invention.

FIG. 40 depicts a top view of the semiconductor structure of FIG. 39, according to an embodiment of the invention.

FIG. 41 depicts a cross-sectional view of a semiconductor structure following removal of unwanted anneal semiconductor material to form active areas for planar FETs or FinFETs, according to an embodiment of the invention.

FIG. 42 depicts a top view of the semiconductor structure of FIG. 41, according to an embodiment of the invention.

FIG. 43 depicts a cross-sectional view of a semiconductor structure following formation of seed structures with different semiconductor materials, according to an embodiment of the invention.

FIG. 44 depicts a top view of the semiconductor structure of FIG. 43, according to an embodiment of the invention.

FIG. 45 depicts a cross-sectional view of the semiconductor structure from FIG. 43 following planar FET formation, according to an embodiment of the invention.

FIG. 46 depicts a top view of the semiconductor structure of FIG. 45, according to an embodiment of the invention.

FIG. 47 depicts a cross-sectional view of a semiconductor structure illustrating a first process for wedge-shaped groove formation, according to an embodiment of the invention.

FIGS. 48 and 49 depict cross-sectional views of a semiconductor structure illustrating a second process for wedge-shaped groove formation using a thin mask, according to an embodiment of the invention.

FIGS. 50 and 51 depict cross-sectional views of a semiconductor structure illustrating a second process for wedge-shaped groove formation using a thick mask, according to an embodiment of the invention.

FIGS. 52-55 depict cross-sectional views of a semiconductor structure illustrating a continuation of second process for wedge-shaped groove formation following first oblique trench formation using the thin or thick hardmask, according to an embodiment of the invention.

FIGS. 56, 58, 60, 62 and 64 depict cross-sectional views of a semiconductor structure illustrating a third process for wedge-shaped groove formation, according to an embodiment of the invention.

FIGS. 57, 59, 61, 63 and 65 depict top views of the semiconductor structure of FIGS. 56, 58, 60, 62 and 64, respectively, according to an embodiment of the invention.

FIGS. 66-68 depict cross-sectional views of a semiconductor structure illustrating a fourth process for wedge-shaped groove formation, according to an embodiment of the invention.

FIG. 69 depicts a flow chart of a process for manufacturing a semiconductor device including a plurality of crystalline seed structures, according to an embodiment of the invention.

FIG. 70 depicts a representation of amorphous semiconductor material and a wedge-shaped seed structure including crystallized semiconductor material, according to an embodiment of the invention.

FIG. 71 depicts a representation of seed structures for different groove wall angles, according to an embodiment of the invention.

FIG. 72 depicts a plot of nucleation rates at different groove wall angles, according to an embodiment of the invention.

### DETAILED DESCRIPTION

Illustrative embodiments of the invention may be described herein in the context of illustrative methods for forming oriented crystal seed structures in semiconductor device dielectric layers, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention may be discussed in connection with nanosheet stacks, the embodiments of the present invention are not necessarily limited thereto, and may similarly apply to nanowire stacks.

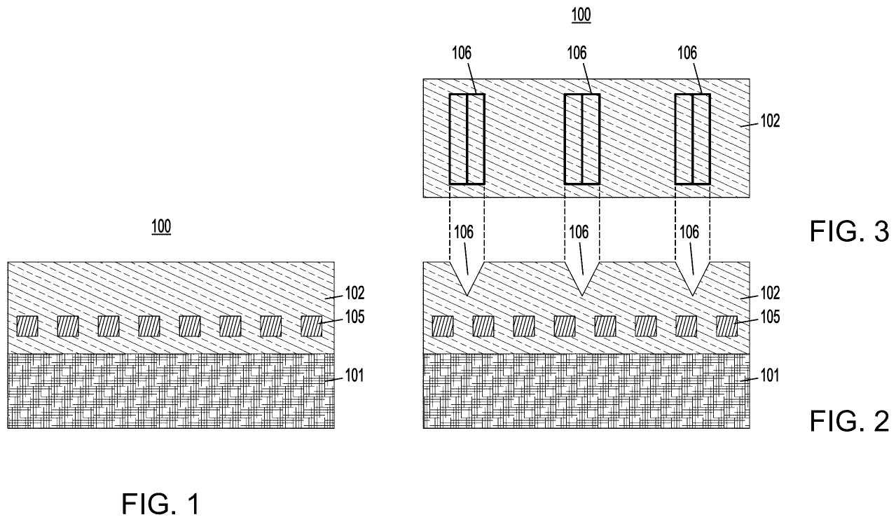

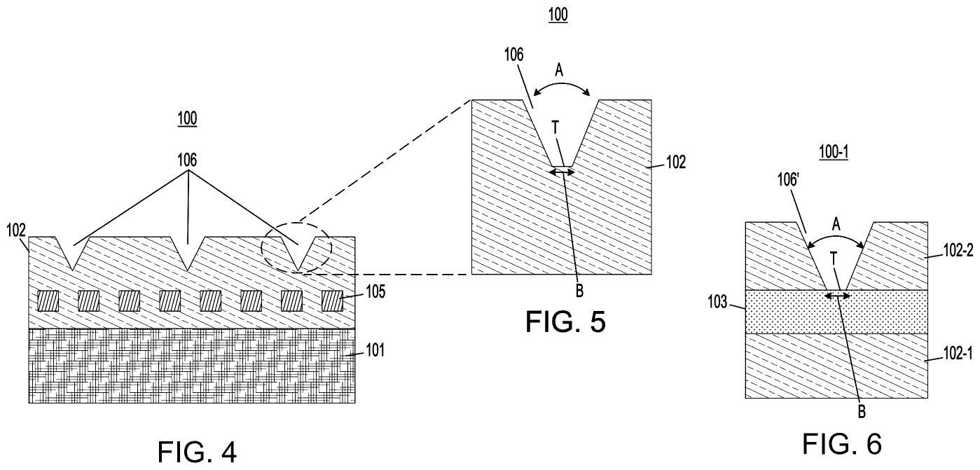

Referring to FIG. 1, a semiconductor structure 100 includes at least one dielectric layer 102 on a semiconductor substrate 101. The semiconductor substrate 101 includes semiconductor material including, but not limited to, silicon (Si), III-V, II-V compound semiconductor materials or other like semiconductor materials. In addition, multiple layers of the semiconductor materials can be used as the semiconductor material of the semiconductor substrate 101. In illustrative embodiments, the semiconductor substrate 101 can include various structures and devices such as, but not necessarily limited to, transistors, dielectric isolation layers, middle-of-line (MOL) and/or BEOL interconnects, power distribution networks, etc. The semiconductor substrate 101 can include crystalline semiconductor materials. In some embodiments, the semiconductor substrate 101 lacks crystalline semiconductor materials, for example, in the case of a glass substrate.

The dielectric layer 102 can include, for example, silicon oxide (SiOₓ) (where x is for example, 2, 1.99 or 2.01), silicon oxycarbide (SiOC), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof. In illustrative embodiments, the dielectric layer 102 is deposited on the semiconductor substrate 101 using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). Interconnects 105 can be formed in the dielectric layer 102 to connect to, for example, transistors, MOL interconnects, BEOL interconnects and/or power distribution networks in the semiconductor substrate 101.

Referring, for example, to a first alternative semiconductor structure 100-1, there can be multiple dielectric layers, for example, a first dielectric layer 102-1, a second dielectric layer 103 and a third dielectric layer 102-2, in a stacked configuration on the semiconductor substrate 101. In an illustrative embodiment, the first and third dielectric layers 102-1 and 102-2 are the same material as each other and the second dielectric layer 103 is a different material from the first and third dielectric layers 102-1 and 102-2. The materials of the first and third dielectric layers 102-1 and 102-2 and of the second dielectric layer 103 can be, for example, a combination of the two or more of the materials noted for the dielectric layer 102.

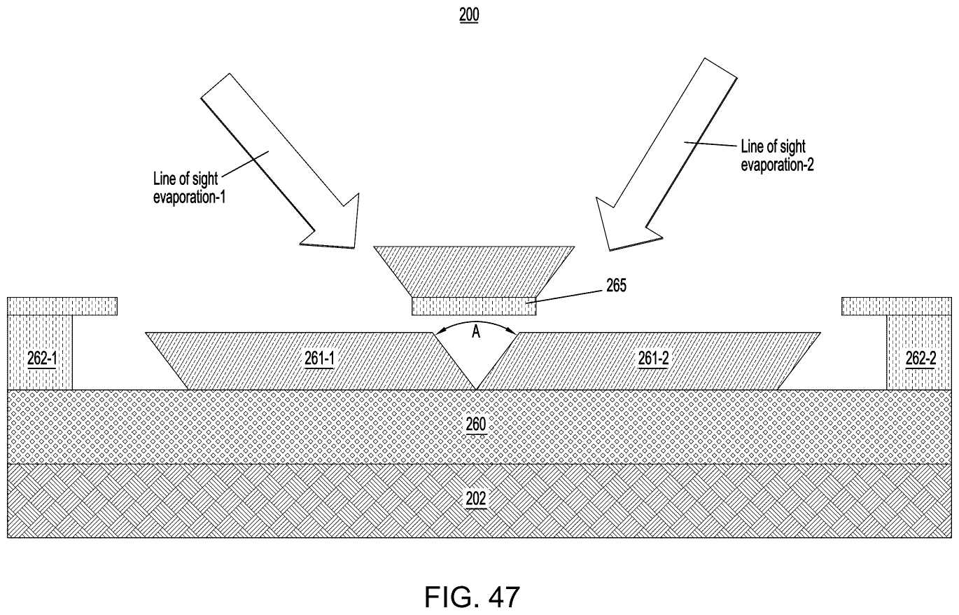

Referring to FIGS. 2 and 3, a plurality of wedge-shaped (e.g., V-shaped) grooves 106 are formed in the dielectric layer 102. Similarly, one or more wedge-shaped (e.g., V-shaped) grooves 106′ are formed in the third dielectric layer 102-2 of the first alternative semiconductor structure 100-1. As can be seen in FIG. 3, each of the wedge-shaped grooves 106 (and similarly the wedge-shaped groove 106′) has a length (vertical direction in FIG. 3) across a top surface of the dielectric layer 102 (or third dielectric layer 102-2) and a width in the horizontal direction in FIGS. 2 and 3. The wedge-shaped grooves 106/106′ have a tapered shape with a decreasing width in a downward direction from a top surface of the dielectric layer 102 or third dielectric layer 102-2. As described in more detail herein in connection with FIGS. 47 to 68, there are multiple processes for forming the wedge-shaped grooves 106/106′ including, for example, directional deposition, oblique deposition, directional, tilted etching, oblique directional material modification and molding, and a combination of isotropic and directional etching.

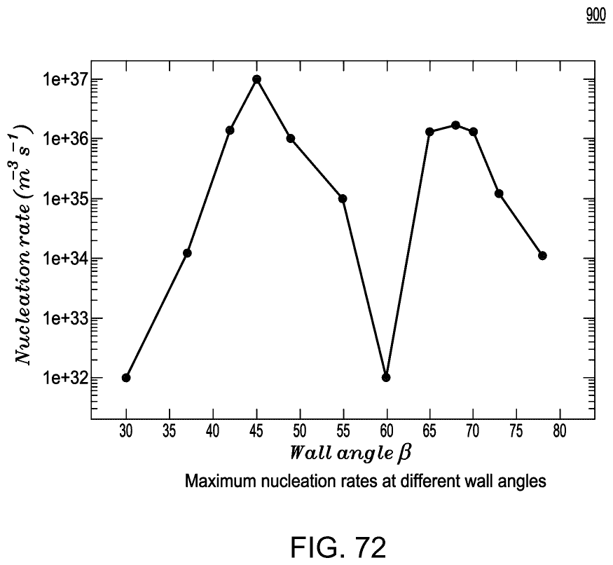

As can be seen in FIGS. 5 and 6, the wedge-shaped grooves 106/106′ include a first wall and a second wall opposite the first wall (also referred to herein as a first side and a second side). An angle A between the first wall and the second wall is in a range of about 40 degrees to about 75 degrees. More particularly, as discussed in more detail herein connection with the plot 900 in FIG. 72, in an illustrative embodiment, an angle A in the range of about 40 degrees to about 55 degrees or in the range of about 65 degrees to about 73 degrees provides maximum nucleation rates when crystallizing semiconductor material in the wedge-shaped grooves 106/106′. As can be seen in the enlarged views of FIGS. 5 and 6, a tip portion T at the base of each one of the wedge-shaped grooves 106/106′ has a certain width B in the horizontal direction determining a sharpness of the tip portion T. In illustrative embodiments, the width B is in the range of about 0.5 nm to about 50 nm with the range of about 1 nm to about 10 nm being more typical.

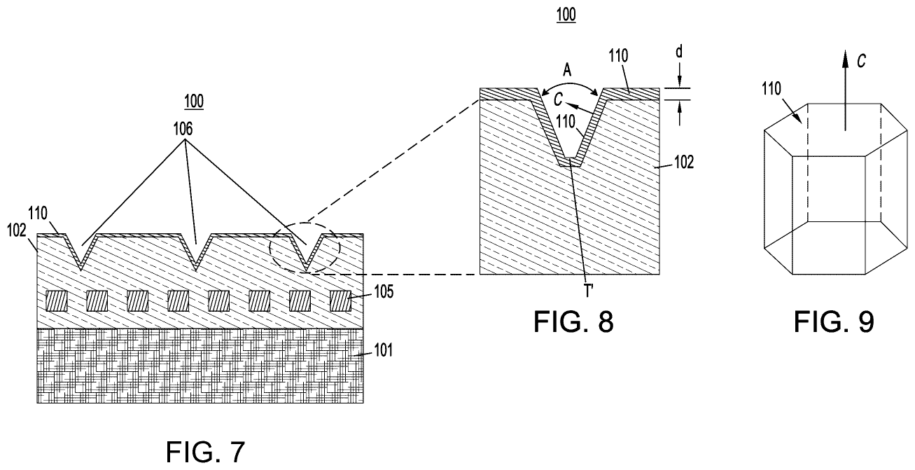

Referring to FIGS. 7-9, first and second walls (sides) of respective ones of the plurality of wedge-shaped grooves 106 are lined with a liner layer 110 including a crystalline film material having hexagonal symmetry. More particularly, the liner layer 110 includes a hexagonal polycrystalline material such as, for example, a polycrystalline oxide or polycrystalline nitride (e.g., titanium nitride (TiN), tantalum nitride (TaN), SiN). In illustrative embodiments, the liner layer 110 is deposited conformally using, for example, conformal deposition techniques such as CVD or ALD. The liner layer can be deposited as a polycrystalline material or, following deposition, the liner layer 110 is crystallized using a thermal annealing technique into a textured polycrystalline phase. Referring to FIGS. 8 and 9, the liner layer 110 has a c axis of its hexagonal crystal symmetry pointing outward from the wall surfaces.

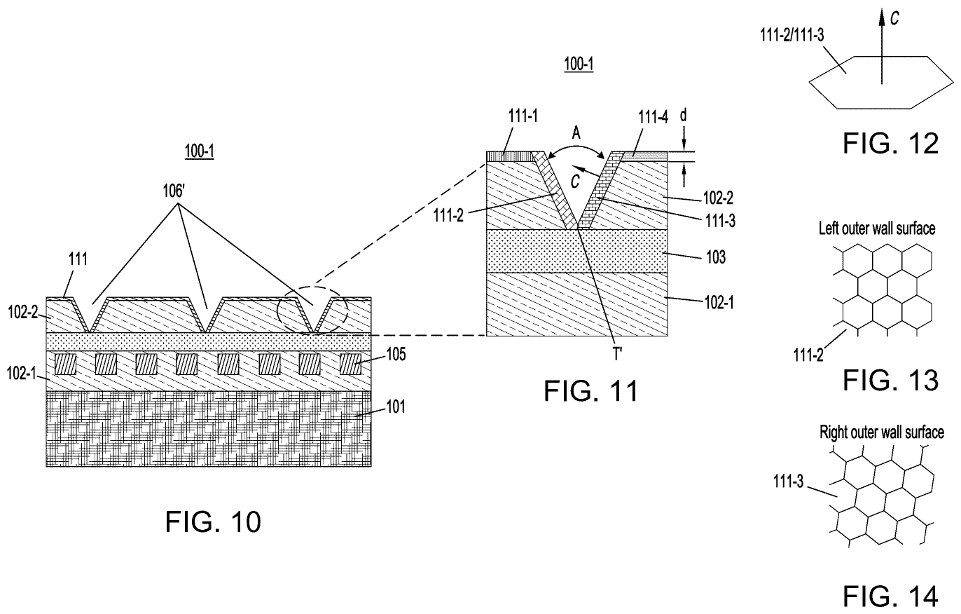

Like the liner layer 111 described in connection with FIGS. 10-14, the crystal grains of the liner layer 110 can have a different rotation with respect to the c axis on different groove walls and top surfaces of the dielectric layer 102. A thickness d of the liner layer is about one-half the original tip width B so that the modified tip portion T′ is sharp. As explained in more detail herein, the modified tip portion T′ is about 1 atomic spacing to about 3 atomic spacings of resulting crystal material after annealing.

Referring to FIGS. 10 and 11, in the first alternative semiconductor structure 100-1, first and second walls (sides) of respective ones of the plurality of wedge-shaped grooves 106′ are lined with a liner layer 111 including a crystalline film material having hexagonal symmetry. More particularly, the liner layer 111 includes a hexagonal 2D material such as, for example, layered 2D material selected from graphene, hexagonal-BN (h-BN) and metal-chalcogens. As can be seen by the different portions 111-1, 111-2, 111-3 and 111-4 of the liner layer 111, the crystal grains of the liner layer 111 can have a different rotation with respect to the c axis on different groove walls and top surfaces of the dielectric layer 102. For example, FIGS. 13 and 14 illustrate different rotations with respect to the c axis of crystal grains of liner layer portions 111-2 and 111-3 on left and right groove walls.

In illustrative embodiments, the material of a second dielectric layer 103 and the material of a third dielectric layer 102-2 can be selected to suppress and promote nucleation of 2D materials, respectively. A thickness d of the liner layer 111 is about one-half the original tip width B so that the modified tip portion T′ is sharp.

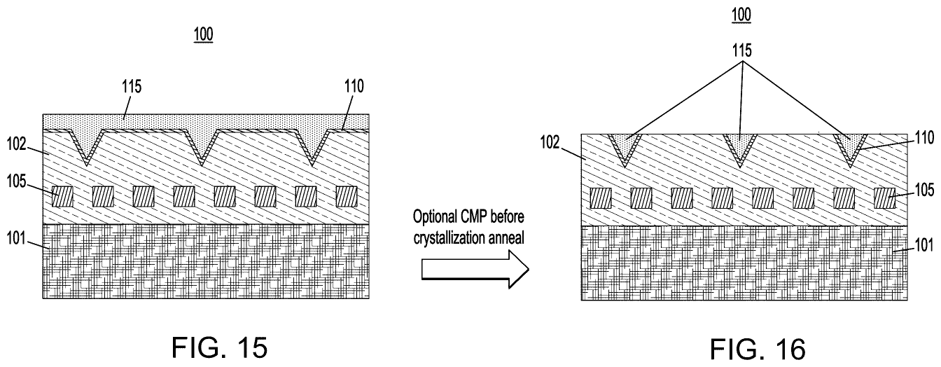

Referring to FIG. 15, amorphous group-IV semiconductor material 115 is deposited on the liner layer 110 in the wedge-shaped grooves 106. Although not shown, amorphous group-IV semiconductor material 115 can similarly be deposited on the liner layer 111 in the wedge-shaped grooves 106′. The amorphous group-IV semiconductor material 115 includes, for example, amorphous silicon (a-Si), amorphous germanium (a-Ge), amorphous silicon germanium (a-SiGe) or other amorphous group-IV semiconductors. The amorphous group-IV semiconductor material 115 is also deposited on the top surface of the dielectric layer 102 and fills in the wedge-shaped grooves 106. The deposition is performed using deposition techniques such as, for example, CVD, PECVD, RFCVD, PVD, ALD, MBD, PLD and/or LSMCD. Referring to FIG. 16, an optional a planarization process, such as, chemical mechanical planarization (CMP) can be performed following the deposition and before annealing to remove excess portions of the liner layer 110 and the amorphous group-IV semiconductor material 115 from the top surface of the dielectric layer 102.

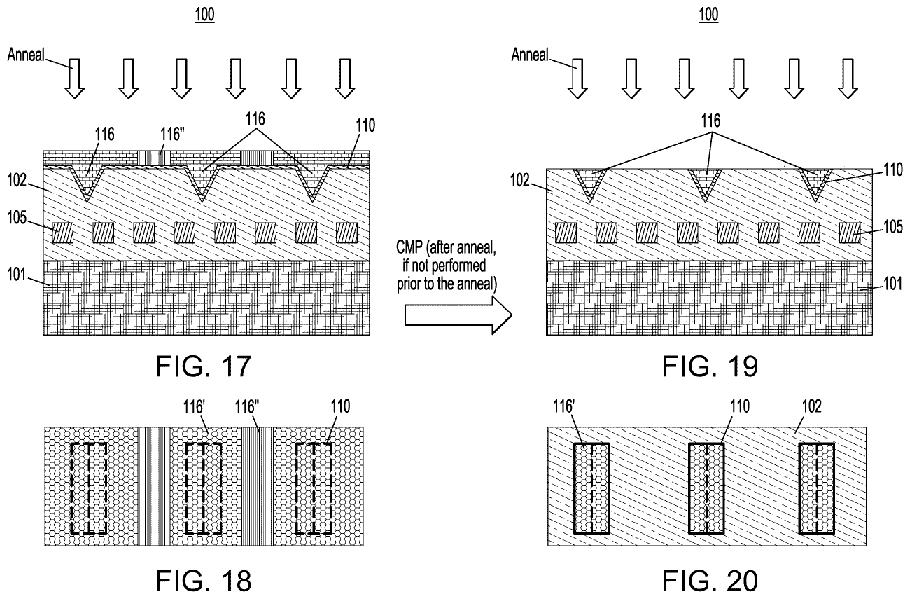

Referring to FIGS. 17 and 18, following from FIG. 15, if planarization was not performed, an annealing process is performed. In illustrative embodiments, the annealing process includes ultra-short duration anneals (e.g., laser annealing, flash annealing, electron beam (e-beam) annealing). In illustrative embodiments, the duration of annealing is selected to first liquify (e.g., melt) the amorphous group-IV semiconductor material 115 and then allow the amorphous group-IV semiconductor material 115 to crystallize. In illustrative embodiments, the duration of annealing is in a range from about 5 ns to about 1 μs.

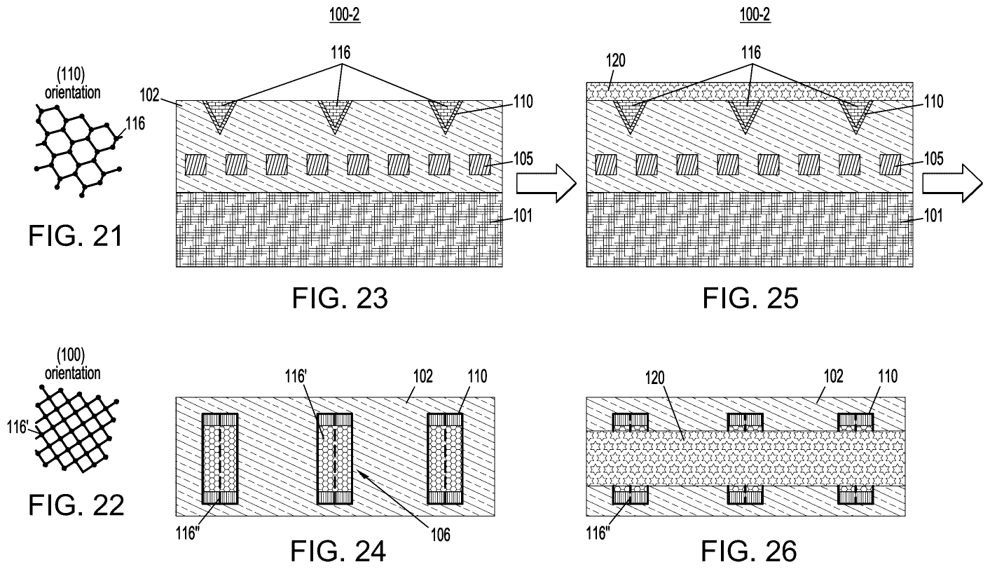

The crystallized semiconductor material includes body portions 116, surface portions 116′ and undefined crystal orientation areas 116″ caused by colliding growth fronts. Each body portion 116 is an oriented single-crystalline semiconductor seed structure having a (110) crystal orientation in a plane perpendicular to top surfaces of the dielectric layer 102 and the semiconductor substrate 101. Each surface portion 116′ is an oriented single-crystalline semiconductor seed structure having a (100) crystal orientation in a plane parallel to top surfaces of the dielectric layer 102 and the semiconductor substrate 101. FIG. 21 depicts a lattice arrangement of crystalline material (e.g., crystalline material of body portions 116) in a (110) orientation. FIG. 22 depicts a lattice arrangement of crystalline material (e.g., crystalline material of surface portions 116′) in a (100) orientation.

Referring to FIGS. 19 and 20, if planarization was not performed following the deposition of the amorphous group-IV semiconductor material 115 and before annealing, the structure from FIGS. 17 and 18 is planarized to remove crystallized semiconductor material and portions of the liner layer 110 from the top surface of the dielectric layer 102 to result in the structure of FIGS. 19 and 20. Alternatively, if planarization was performed following the deposition of the amorphous group-IV semiconductor material 115 and before annealing as shown in FIG. 16, the annealing process is performed on the FIG. 16 structure to result in the structures of FIGS. 19 and 20. As can be seen in FIGS. 19 and 20, the resulting structure includes the crystallized semiconductor material including the body portions 116 and surface portions 116′. The undefined crystal orientation areas 116″ are not formed due to planarization prior to annealing or are removed in a planarization step following annealing.

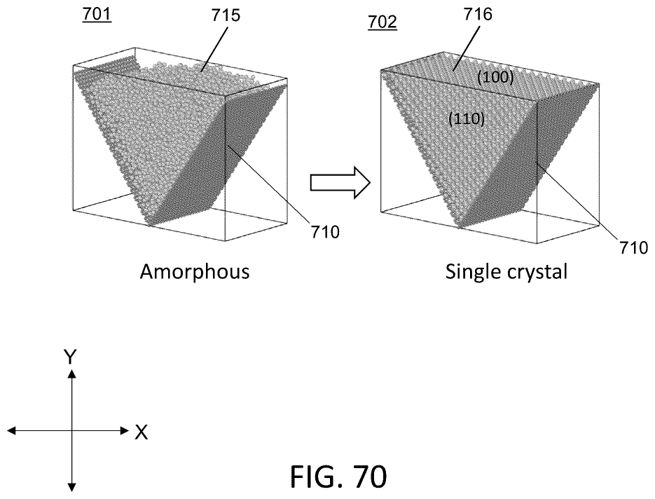

Referring to the representation 701 of amorphous semiconductor material and the representation 702 of a wedge-shaped seed structure including crystallized semiconductor material in FIG. 70, a single-crystal 716 of group IV elements is formed in each wedge-shaped groove (e.g., wedge-shaped grooves 106 and 106′) by confining and crystallizing amorphous group-IV semiconductor material 715 within the wedge-shaped groove with an atomically sharp tip (e.g., modified tip portion T′). The confining material 710 (e.g., liner layer 110 or 111) of the walls of the seed structure has a hexagonal crystalline symmetry. As noted herein, such confining material includes, for example, polycrystalline oxides or nitrides, graphene, hexagonal boron-nitride (h-BN), metal-chalcogens, etc. Using an annealing process, the amorphous semiconductor material is heated and enters the liquid state. Crystallization begins at a base of the wedge-shaped groove (e.g., V-shaped groove) at a tip portion, where atoms are kinetically arrested and able to arrange in ordered patterns. The critical nucleus is obtained from the expansion along the tip and towards the perpendicular axis. A sharpness of the tip portion (e.g., modified tip portion T′) is in a range of about 1 atomic spacing to about 3 atomic spacings of the crystallized semiconductor material also referred to herein as “semiconductor crystalline material”). As noted in the representation 702, a body portion of the single-crystal 716 is in a (110) orientation in a plane along the y-axis, and surface portion of the single-crystal 716 is in a (100) orientation in a plane along the x-axis.

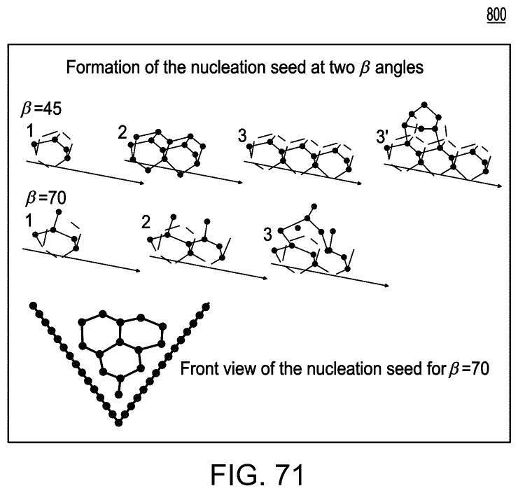

FIG. 71 depicts a representation 800 of seed structures for different groove wall angles A of 45 degrees and 75 degrees. FIG. 72 depicts a plot 900 of maximum nucleation rates at different groove wall angles. As can be seen in the plot 900, nucleation rates are relatively higher for angles of 40-55 degrees and for angles of 65-73 degrees. The seed structures are formed as a single crystal that can be adopted as a crystallization seed for further growth (e.g., epitaxial growth) of semiconductor layers used in semiconductor devices such as, for example, FETs. Advantageously, the embodiments work for multiple group-IV semiconductor materials, and the confining material 710 can include a variety of different materials with hexagonal symmetry.

Referring back to FIGS. 23-28, in another embodiment, as can be seen in FIGS. 24 and 26, a semiconductor structure 100-2 includes undefined crystal orientation areas 116″ (e.g., defective crystal) within the wedge-shaped grooves 106, which can be formed due to edge effects. As can be seen in FIGS. 25 and 26, in a process to remove the undefined crystal orientation areas 116″, body and surface portions 116 and 116′ including properly oriented single-crystalline semiconductor seed structures, are masked with a mask 120, leaving the undefined crystal orientation areas 116″ exposed. The mask 120 can include, for example, a soft polymer-based mask (e.g., a photoresist, ODL material) or a hard mask such as SiN.

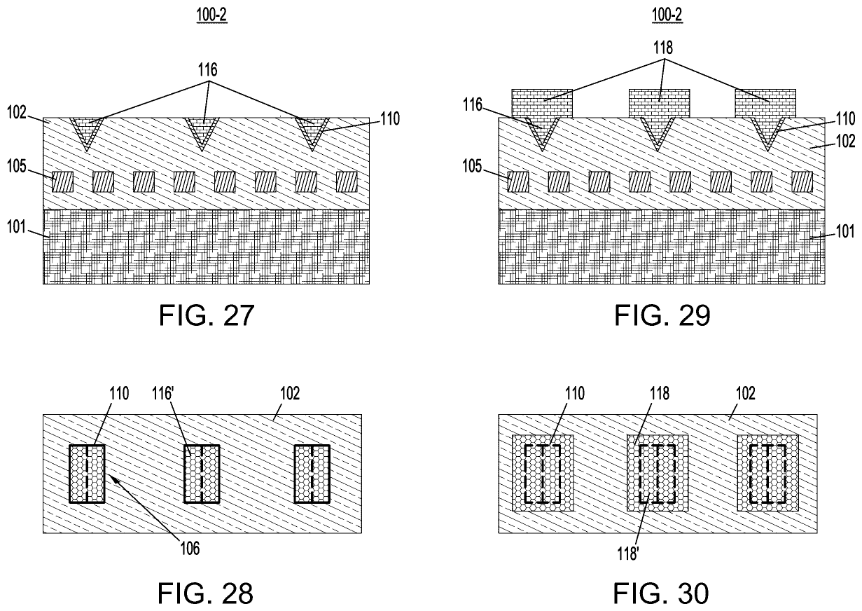

Referring to FIGS. 27 and 28, the exposed undefined crystal orientation areas 116″ and underlying portions of the liner layer 110 are removed from the wedge-shaped grooves 106 using, for example, a RIE etching process including RIE based on chlorine or bromine containing plasmas. Then, following removal, vacant areas of the wedge-shaped grooves 106 are filled in dielectric material which is the same as or similar to the material of the dielectric layer 102. A planarization process such as, for example, CMP, is performed after depositing the dielectric fill material.

As noted herein above, the seed structures are formed in the wedge-shaped grooves 106/106′ as a single crystal that can be adopted as a crystallization seed for further growth (e.g., epitaxial growth) of semiconductor layers used in semiconductor devices such as, for example, FETs. Referring to FIGS. 29 and 30, the seed structures include the crystallized semiconductor material including the body portions 116 and surface portions 116′ at different orientations. An epitaxial growth process is performed to form crystalline over layers similarly including additional body portions 118 and additional surface portions 118′ including single-crystalline semiconductor material in the same orientation as the underlying seed structures. More specifically, each additional body portion 118 is an oriented single-crystalline semiconductor structure having a (110) crystal orientation in a plane perpendicular to top surfaces of the dielectric layer 102 and the semiconductor substrate 101. Each additional surface portion 118′ is an oriented single-crystalline semiconductor structure having a (100) crystal orientation in a plane parallel to top surfaces of the dielectric layer 102 and the semiconductor substrate 101.

In illustrative embodiments, low-temperature (e.g., <450° C.) epitaxy can be used to form the crystalline over layers. Alternatively, deposition of amorphous semiconductor material over the seed structures is performed, and epitaxial re-growth is initiated by ultra-short duration anneals (e.g., laser, flash, e-beam) to form the crystalline over layers. The re-grown crystalline over layers retains the orientation of the crystalline seed structures. In-situ doped active area wells can be formed by the low-temperature epitaxy or by heated (hot) ion implantation and ultra-short duration anneals.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed structures). In an epitaxial deposition process, the chemical reactants provided by the source gases are controlled, and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has the same or substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof.

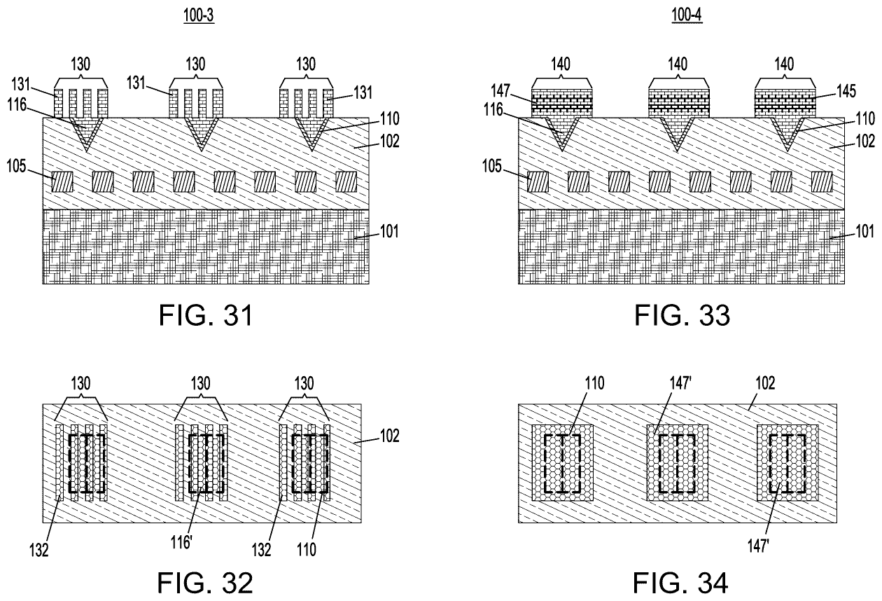

Referring to the semiconductor structure 100-3 in FIGS. 31 and 32, in connection with the formation of FinFETs, the crystalline over layers are patterned to form fins 130. Like the additional body portions 118 and additional surface portions 118′, fin body portions 131 have a (110) crystal orientation in a plane perpendicular to top surfaces of the dielectric layer 102 and the semiconductor substrate 101 fin surface portions 132 have a (100) crystal orientation in a plane parallel to top surfaces of the dielectric layer 102 and the semiconductor substrate 101.

Referring to the semiconductor structure 100-4 in FIGS. 33 and 34, in connection with the formation of nanosheet FETs, in epitaxial processes similar to those described in connection with the semiconductor structure 100-4 of FIGS. 29 and 30, alternating layers of different semiconductor materials are epitaxially grown from the seed structures, including the body and surface portions 116 and 116′, to form nanosheet stacks 140. For example, nanosheet stacks 140 include sacrificial layers 145 and channel layers 147 which are epitaxially grown in an alternating and stacked configuration on the seed structures. A first sacrificial layer 145 is followed by a first channel layer 147 on the first sacrificial layer 145, which is followed by a second sacrificial layer 145 on the first channel layer 147, and so on. As can be understood, the sacrificial and channel layers 145 and 147 are epitaxially grown from their corresponding underlying semiconductor layers. Body portions of the channel layers 147 have a (110) crystal orientation in a plane perpendicular to top surfaces of the dielectric layer 102 and the semiconductor substrate 101, while surface portions 147′ of the channel layers 147 as shown in the top view in FIG. 34, have a (100) crystal orientation in a plane parallel to top surfaces of the dielectric layer 102 and the semiconductor substrate 101.

While two sacrificial layers 145 and three channel layers 147 are shown, the embodiments of the present invention are not necessarily limited to the shown number of sacrificial and channel layers 145 and 147, and there may be more or less layers in the same alternating configuration depending on design constraints. The sacrificial layers 145, as described further herein, are eventually removed and replaced by gate structures.

In illustrative embodiments, SiGe can be sacrificial material for sacrificial layers 145, but other materials can be used as long as the sacrificial layers 145 have the property of being able to be removed selectively compared to the material of the channel layers 147. In illustrative embodiments, silicon can be the material of the channel layers 147, so that the nanosheet stacks 140 include, for example, a superlattice of silicon and SiGe layers.

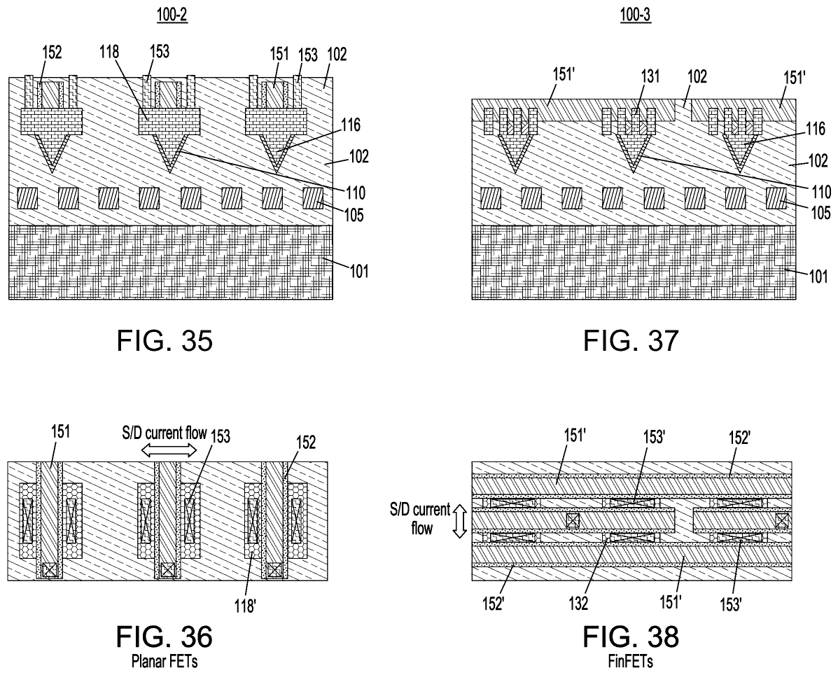

FIGS. 35 and 36 depict cross-sectional and top views of the semiconductor structure 100-2 following planar FET formation. Referring to FIGS. 35 and 36, using, for example, lateral channel undercut processing and low temperature (e.g., <450° C.) epitaxial growth processes, source/drain regions 153 with active doping are formed on sides of gate regions 151 and gate spacers 152, which are formed on the gate regions 151. As shown in FIG. 36, source-to-drain (S-D), transistor current flow is along the plane parallel to top surfaces of the dielectric layer 102 and the semiconductor substrate 101. The S-D current flows in the (100) crystal orientation plane along the <110> direction.

FIGS. 37 and 38 depict cross-sectional and top views of the semiconductor structure 100-3 following FinFET formation. Referring to FIGS. 37 and 38, using, for example, lateral channel undercut processing and low temperature (e.g., <450° C.) epitaxial growth processes, source/drain regions 153′ with active doping are formed on sides of gate regions 151′ and gate spacers 152′, which are formed on gate regions 151′. As shown in FIG. 38, source-to-drain (S-D), transistor current flow is primarily along the plane perpendicular to top surfaces of the dielectric layer 102 and the semiconductor substrate 101. The S-D current flows primarily in the (110) crystal orientation plane along the <110> direction.

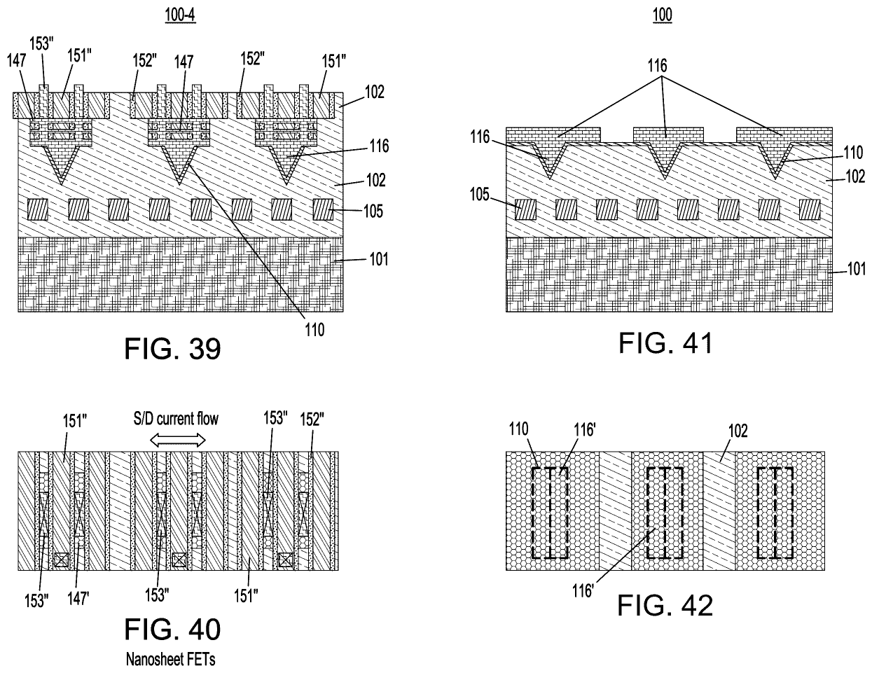

FIGS. 39 and 40 depict cross-sectional and top views of the semiconductor structure 100-4 following nanosheet FET formation. Referring to FIGS. 39 and 40, using, for example, lateral channel undercut processing and low temperature (e.g., <450° C.) epitaxial growth processes, source/drain regions 153″ with active doping are formed on sides of gate regions 151″ including gate spacers 152″ formed thereon, and on sides of nanosheet stacks. As shown in FIG. 40, source-to-drain (S-D), transistor current flow is primarily along the plane parallel to top surfaces of the dielectric layer 102 and the semiconductor substrate 101. The S-D current flows in the (100) crystal orientation plane along the <110> direction.

In illustrative embodiments, in connection with the semiconductor structures 100-2, 100-3 and 100-4, short-duration (e.g., laser, flash, e-beam) anneals can be employed to do post deposition anneals for gate stack materials and further doping activation and contact formation. Heated ion implantation with substrate temperature lower than 450° C. can be employed to implant dopants without requiring prolonged defect annealing. Low-temperature (<450° C.) selective gas phase epitaxy with in-situ doping can be employed to form doped and highly activated crystalline source/drain regions. A low-temperature (<450° C.) interfacial metal silicidation process of highly-doped S/D region can be employed to form low-resistance semiconductor-metal contacts.

As can be understood, the material of the gate spacers 152, 152′ and 152″ can include for example, one or more dielectrics, including, but not necessarily limited to, SiN, SiON, SiOC, SiCN, BN, SiBN, SiBCN, SiOCN, SiOₓ, and combinations thereof. In the case of n-type FETS (nFETs), the source/drain regions 153, 153′ and 153″ can include silicon doped with n-type dopants including, for example, phosphorus (P), arsenic (As) and antimony (Sb). In the case of p-type FETS (pFETs), the source/drain regions 153, 153′ and 153″ can include silicon doped with p-type dopants including, for example, boron (B), boron fluoride (BF₂), gallium (Ga), indium (In), and thallium (Tl).

In illustrative embodiments, each gate region 151, 151′ and 151″ includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). According to an embodiment, the gate regions 151, 151′ and 151″ each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Referring back to FIGS. 29 and 30, as described herein above, in the semiconductor structure 100-2, an epitaxial growth process is performed to form crystalline over layers including additional body portions 118 and additional surface portions 118′. Referring to FIGS. 41 and 42, as an alternative to the semiconductor structure 100-2, in the semiconductor structure 100, instead of performing a planarization step after formation of the crystallized semiconductor material including body portions 116, surface portions 116′ and undefined crystal orientation areas 116″ in FIG. 17, the undefined crystal orientation areas 116″ and underlying portions of the liner layer 110 are removed in via one or more etching processes. The etching processes include, for example, an RIE process based on chlorine or bromine containing plasmas. Then, the remaining crystallized semiconductor material, which was not removed, and remains on top of the dielectric layer 102 and on top of the portions of the seed structures in the wedge-shaped grooves 106, is used like the epitaxially grown crystalline over layers from FIGS. 29 and 30 as the base epitaxial layers required for forming transistors like those described in connection with FIGS. 35-40.

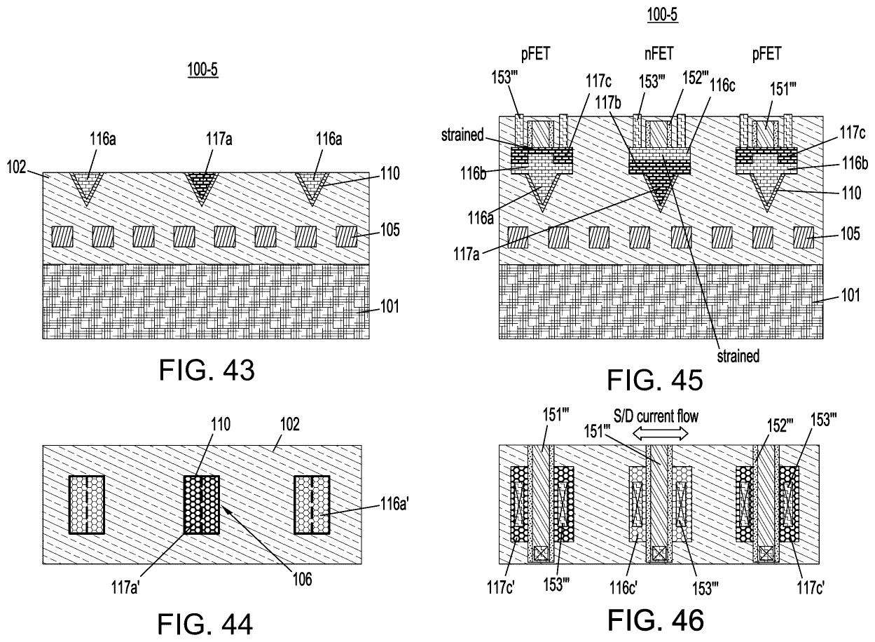

FIGS. 43 and 44 depict cross-sectional and top views of another semiconductor structure 100-5 following formation of seed structures with different semiconductor materials. Similar to the semiconductor structures 100 and 100-2 described in connection with FIGS. 19 and 27, the semiconductor structure 100-5 in FIGS. 43 and 44 includes seed structures formed in wedge-shaped grooves 106, except that one or more of the seed structures have different materials. For example, in an illustrative embodiment, first seed structures including body portions 116a and surface portions 116a′ include the same materials as each other and as the seed structures in the semiconductor structures 100 and 100-2. A second seed structure including body portion 117a and surface portion 117a′ is disposed adjacent and between the first seed structures and includes a different material (e.g., different group-IV semiconductor) from the first seed structures. In a non-limiting illustrative embodiment, the first seed structures include silicon, while the second seed structures include SiGe. In other respects, the semiconductor structure 100-5 is the same as semiconductor structure 100-2 described in connection with FIG. 27.

FIGS. 45 and 46 depict cross-sectional and top views of the semiconductor structure 100-5 following planar FET formation. The semiconductor structure 100-5 includes two pFETs and one nFET with different channel stressors. The two pFETs are formed on top of the first seed structures and the nFET is formed on top of the second seed structure. The pFETs each include a first layer 116b epitaxially grown to include the same material (e.g., Si) as the underlying first seed structure and a strained layer 117c epitaxially grown to include a different material (e.g., SiGe) than the underlying first layer 116b. The nFET includes an additional first layer 117b epitaxially grown to include the same material (e.g., SiGe) as the underlying second seed structure and an additional strained layer 116c grown to include a different material (e.g., Si) than the underlying additional first layer 117b. Surface portions 116c′ and 117c′ of the additional strained layer 116c and the strained layer 117c have a different orientation (e.g., (100) crystal orientation) than an orientation (e.g., (110) crystal orientation) of body portions of the additional strained layer 116c and the strained layer 117c.

Like the semiconductor structure 100-2 described in connection with FIGS. 35 and 36, referring to FIGS. 45 and 46, using, for example, lateral channel undercut processing and low temperature (e.g., <450° C.) epitaxial growth processes, source/drain regions 153′″ with active doping are formed on sides of gate regions 151′″ and gate spacers 152′″, which are formed on the gate regions 151′″. As shown in FIG. 46, source-to-drain (S-D), transistor current flow is along the plane parallel to top surfaces of the dielectric layer 102 and the semiconductor substrate 101. The S/D current flows in the (100) crystal orientation plane along the <110> direction. In other respects, the semiconductor structure 100-5 is the same as semiconductor structure 100-2 described in connection with FIGS. 35 and 36.

As noted herein above, there are various methods for forming wedge-shaped grooves (e.g., wedge-shaped grooves 106/106′). For example, FIG. 47 depicts a cross-sectional view of a semiconductor structure 200 illustrating a directional deposition process for wedge-shaped groove formation through a line-of-sight deposition that substantially coats the surfaces that are directly in line of sight or the deposition source such as but not limited to e-beam evaporation. In one embodiment, the patterning includes the formation of a suspended bridge (for example, the photoresists 262-1, 262-2 in FIG. 47), that act as a closely spaced shadow mask that produces a growth of a layer with a side wall having an angle related to the angle at which the deposition source is positioned. Upon photoresist removal, all layers deposited on top will be removed as well, leaving the surface only with the V-shaped groove which can be formed from the same or different materials provided that they are sufficiently refractory material to withstand the subsequent Si recrystallization temperature, preferably 1414° C. such as, but not limited, to SiO₂ and Al₂O₃ in a technique described below.

Referring to FIG. 47, a bridge 265 is formed by: (1) spin coating 550 nm methyl methacrylate (MMA) and performing a baking process; (2) spin coating 200 nm poly(methyl methacrylate) (PMMA), and performing a baking process; (3) exposing the PMMA to e-beam lithography to create openings from on top of the PMMA at a higher e-beam exposure dose, for example, about 530 μC/cm²; (4) exposing a bridge region to e-beam lithography at a lower dose that is about ¼ of the high dose-in the given example, about 132.5 μC/cm² that is sufficient to remove the MMA, but low enough to not damage the PMMA (e.g., ¼ dose at room temperature); (5) develop the stack with ethanol:water 85% solution for 60 seconds; and (6) perform an ultraviolet (UV) ozone descum process for 10 seconds to clear any possible residue at a substrate surface.

Once a suspended bridge 265 is formed, a first deposition of refractory material 260 (for example, SiO₂) is performed on top of the surface 202 tilted at an angle of 54.7 degrees with respect to the deposition direction, while maintaining a longitudinal axis of the bridge 265 perpendicular to the position of the deposition source. Then, the sample is tilted an additional 70.6 degrees along said axis in the same direction of the original tilt and a second deposition of refractory material that can be the same as 260 (e.g., SiO₂) or different 261-1 (e.g., Al₂O₃) is performed. Then, the photoresist and its overlayers are removed leaving the refractory surface and V-shaped groove.

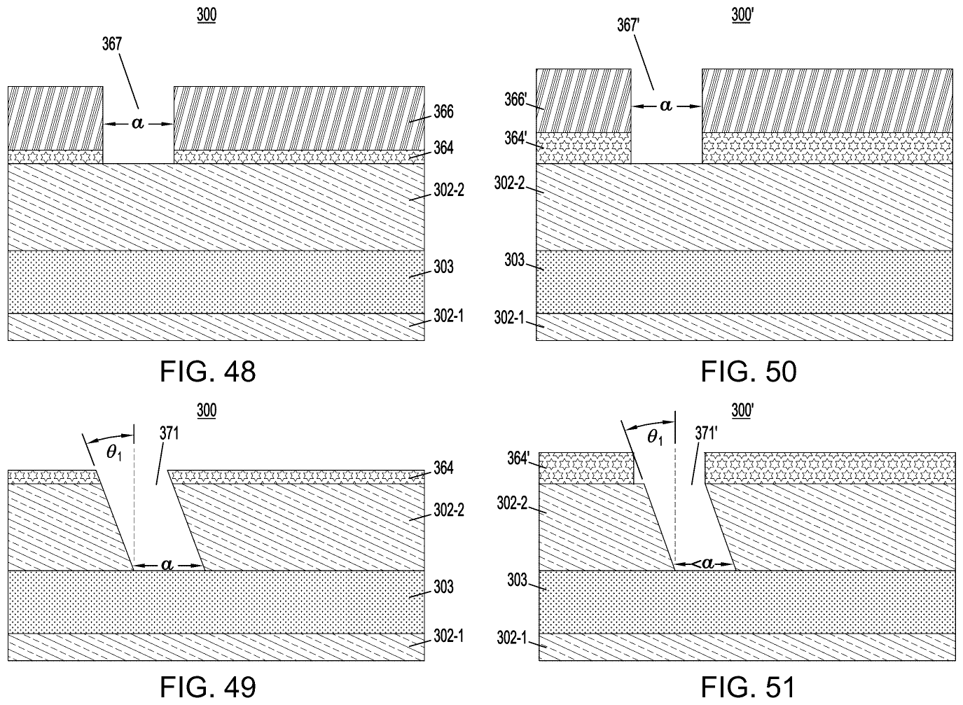

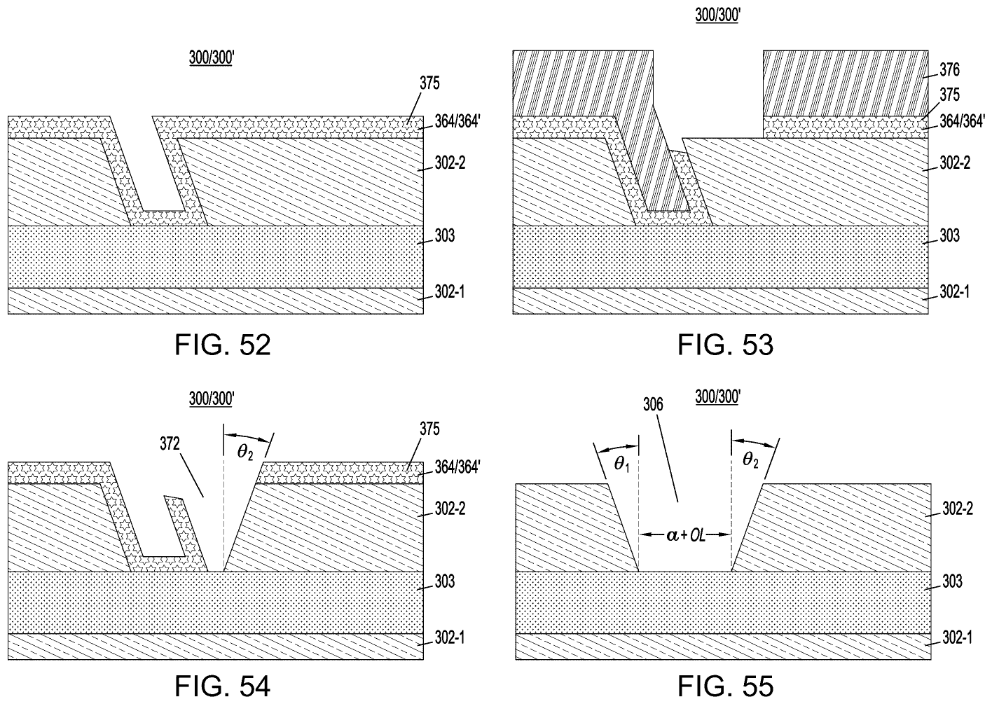

FIGS. 48-55 depict cross-sectional views of a semiconductor structure illustrating a directional, tilted etching process for wedge-shaped groove formation. In FIGS. 48 and 49, the semiconductor structure is labelled 300, when a thin hardmask 364 is used, and in FIGS. 50 and 51, the semiconductor structure is labelled 300′, when a thick hardmask 364′ is used. FIGS. 52-55 depict cross-sectional views of a semiconductor structure 300/300′ illustrating a continuation of the directional, tilted etching process for wedge-shaped groove following first oblique trench formation using the thin or thick hardmask.

In the semiconductor structures 300/300′, a first dielectric layer 302-1, a second dielectric layer 303 and a third dielectric layer 302-2 are formed on a semiconductor substrate (not shown). The first dielectric layer 302-1, second dielectric layer 303 and third dielectric layer 302-2 are the same as or similar to the first dielectric layer 102-1, second dielectric layer 103 and third dielectric layer 102-2 described herein above. Referring to FIG. 48, the thin hardmask 364 and an additional mask layer 366 defining an opening 367 having a width a, are formed on the third dielectric layer 302-2. In FIG. 50, as an alternative what is shown in FIG. 48, the thick hardmask 364′ and an additional mask layer 366′ defining an opening 367′ also having a width a, are formed on the third dielectric layer 302-2. The thin hardmask 364 has a thickness in the vertical direction in the cross-sectional views of 5 nm to 20 nm. The thick hardmask 364′ has a thickness in the vertical direction in the cross-sectional views of 30 nm to 300 nm. The thin and thick hardmasks 364 and 364′ may include, for example, nitride-based materials (e.g., SiN, TiN, TaN) and oxide-based materials (e.g., SiO₂), and the additional mask layers 366 and 366′ may include, for example, the same nitride-based materials as the thin hardmask 364.

As shown in the FIGS. 49 and 51, first oblique trenches 371 and 371′ are etched in the third dielectric layer 302-2 selective to the thin hardmask 364 or thick hardmask 364′, and to the material of the second dielectric layer 303. The etch process includes a directional tilted etch using ion beam techniques (e.g., Raptor® beam etching, commercially available from Applied Materials, Inc.). The tilted etch is performed at a first angle θ₁. Referring to FIG. 51, the option with the thick hardmask 364′ allows for sub-lithographic control of first oblique trench 371′ to permit a width that less than a.

Referring to FIG. 52, following formation of the first oblique trench 371/371′ using the thin hardmask 364 or the thick hardmask 364′, additional hardmask material 375 is deposited to cover trench walls. Referring to FIG. 53, using a second additional mask layer 376 similar to the additional mask layers 366/366′, a second opening 378, which is shifted with respect to the openings 367/367′, is formed with lithography, patterning, and hardmask etching techniques. The location of the second opening 378 with respect to the first openings 367/367′ is subject to lithography overlay tolerance OL. Referring to FIG. 54, a second oblique trench 372 is etched in in the third dielectric layer 302-2 selective to the additional hardmask material 375, remaining thin hardmask 364 or thick hardmask 364′, and to the material of the second dielectric layer 303. The etch process includes a directional tilted etch using ion beam techniques, and is performed at a second angle θ₂. Angles θ₁ and θ₂ can be same or different. Referring to FIG. 55, residual portions of the additional hardmask material 375, thin hardmask 364 or thick hardmask 364′ are removed to complete the wedge-shaped groove 306. The angle between walls of the wedge-shaped groove 306 is equal to the sum of angles θ₁ and θ₂. The width of a tip portion of the wedge-shaped groove 306 is equal to a+OL. The width of the tip portion is defined by a minimum lithographic dimension a, hardmask thickness, and the lithographic overlay tolerance OL.

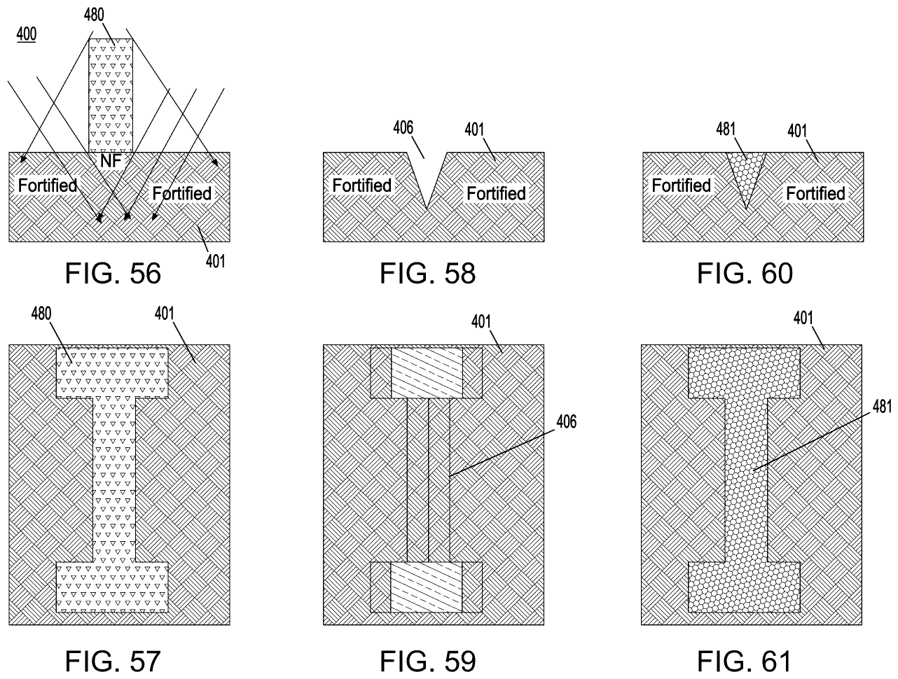

FIGS. 56, 58, 60, 62 and 64 depict cross-sectional views of a semiconductor structure 400 illustrating an oblique, directional material modification and molding process for wedge-shaped groove formation. FIGS. 57, 59, 61, 63 and 65 depict top views of the semiconductor structure of FIGS. 56, 58, 60, 62 and 64, respectively. Referring to the arrows in FIG. 56, energetic beams (e.g., ion beams, electron beams, short-wavelength radiation beams) that reach a substrate (in this case a dielectric layer 401) can cause chemical reactions in and fortify (“fortified”) portions of the substrate against etches. A hardmask 480 that blocks such beams from reaching the substrate (dielectric layer 401) is formed on the substrate and prevents fortification of the blocked portions, which are referred to as “non-fortified (NF).” The hardmask 480 is formed from a material having high stopping power against the beams such as, for example, carbon-based polymers such as resists and organic dielectric layers (ODLs), amorphous-C, etc. In illustrative embodiments, the hardmask 480 is I-shaped.

In illustrative embodiments, the substrate surface is exposed to the energetic beams at an angle by tilting the substrate with respect to the beams and/or tilting the beams with respect to the substrate. In one or more embodiments, when the dielectric layer 401 includes, for example, SiO₂, ion implantation of C, Si and/or N into the dielectric layer 401 may be performed to slow down its each rate. Then, as shown in FIG. 58, the hardmask 480 is removed, and non-fortified portions that were underneath the hardmask 480 are etched to form a wedge-shaped (e.g., V-shaped) groove 406. In some cases, the wedge-shaped groove 406 formation process may end here, and subsequent processing to form seed structures can be performed. However, depending on the material of the dielectric layer 401, modifying the dielectric layer 401 may be difficult and may require high doses of exposure/implantation. In illustrative embodiments, a class of sensitive materials that are designed to undergo a quick fortification upon reasonable doses of energetic beam exposure are used as the dielectric layer 401. Such materials include, for example, polymers with an ability to cross-link their chains upon beam exposure (e.g., hydrogen silsesquioxane (HSQ)). However, although facilitating the fortification process, such materials may not be suitable as permanent isolation layers in a semiconductor device and are employed as a molding material only. In this case, further process steps for creating grooves in permanent isolation structures are performed as shown in FIGS. 60-65.

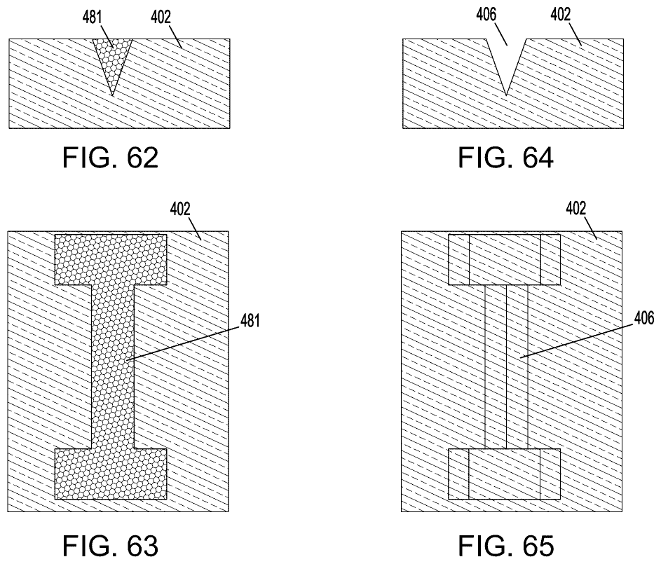

Referring to FIGS. 60 and 61, in the case of a dielectric layer 401 including, for example, polymers with an ability to cross-link their chains upon beam exposure (e.g., HSQ), following formation of a wedge-shaped groove 406, the wedge-shaped groove 406 is filled with a spin-on organic dielectric layer (ODL) material 481 and a planarization process (e.g., CMP) is performed to planarize the ODL material 481. Various temperature-resistant ODL materials can tolerate thermal exposure up to about 400° C. Then, referring to FIGS. 62 and 63, the dielectric layer 401 is selectively removed with respect to the ODL material 481. The ODL material 481 is anchored at the ends of the wedge-shaped groove 406. Following the selective removal of the dielectric layer 401, an additional dielectric layer 402, which may serve as a permanent isolation layer in a resulting semiconductor device, is deposited and planarized to the level of the ODL material 481. Referring to FIGS. 64 and 65, the ODL material 481 is selectively removed with respect to the additional dielectric layer 402 so that the wedge-shaped groove 406 remains in the additional dielectric layer 402. Prior to selectively removing the ODL material 481, the ends of the wedge-shaped groove 406 can be optionally removed. This can be accomplished by blocking a middle groove portion with a mask, selectively removing the ODL material 481 from the groove ends, filling the groove ends with the material of the additional dielectric layer 402, planarizing the filled material the level of the ODL material, and then performing the selective removal of the remaining portions of the ODL material 481.

In some cases, by using the process described in connection with FIGS. 56-65, the wedge-shaped grooves 406, instead of having a V-shape, may be U-shaped due to partial beam blocking near edges of the hardmask 480.

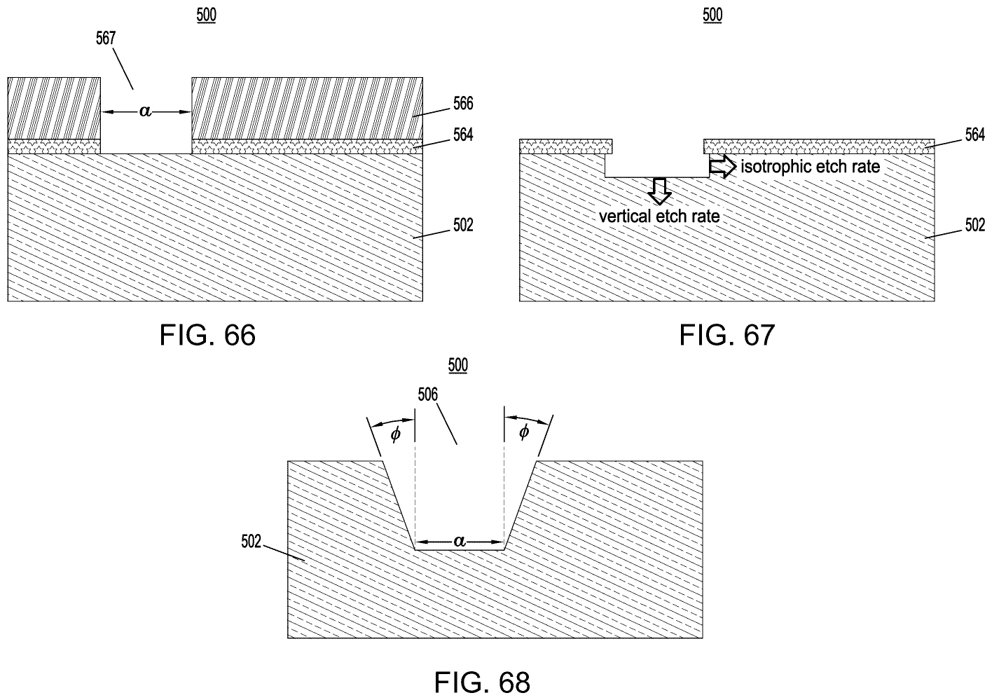

FIGS. 66-68 depict cross-sectional views of a semiconductor structure 500 illustrating a process for wedge-shaped groove formation that includes a combination of isotropic and directional etching. Referring to FIG. 66, a dielectric layer 502 is formed on a semiconductor substrate (not shown). The dielectric layer 502 is the same as or similar to the dielectric layer 102 described herein above. A hardmask 564 and an additional mask layer 566 defining an opening 567 having a width a, are formed on the dielectric layer 502. The hardmask 564 has a thickness in the vertical direction in the cross-sectional views of about 5 nm to about 30 nm. The hardmask 564 may include, for example, nitride-based materials such as SiN, TiN, TaN, and the additional mask layer 566 may include, for example, polymer-based materials such as photoresists or ODL polymer. The opening 567 is defined with lithography, patterning, and hardmask etching techniques. Referring to FIG. 67, a dielectric etch technique is used that provides both directional (vertical etch rate) and isotropic (isotropic etch rate) components. This is accomplished by adding additional reactive gaseous species to a directional RIE process. The vertical etch rate can be controlled by substrate electrical bias during RIE and the isotropic etch rate can be controlled by the amount of active gaseous radicals such as fluorine. Furthermore, forming fluorine- and carbon-based polymer on sidewall surfaces during RIE can be used to control the ratio between vertical and horizontal etch rates. Referring to FIG. 68, the etching process forms a wedge-shaped groove 506, where groove wall angles are controlled by the ratio between isotropic and directional etch rates that, in turn, is controlled by RIE parameters. Left and right wall angles @ are the same due to the isotropic etching component. The depth of the groove should exceed the width “a.”

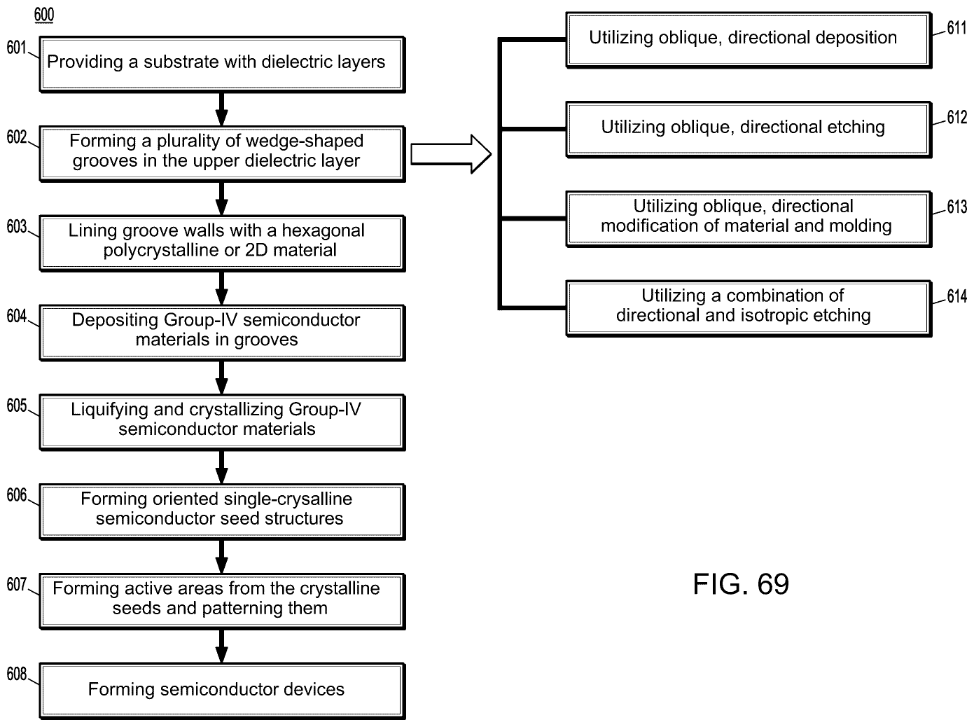

In sum, referring to the process 600 in FIG. 69, at step 601, a semiconductor substrate with dielectric layers on top of the substrate is provided. Referring to step 602, a plurality of elongated wedge-shaped (e.g., V-shaped) grooves having groove walls and a blunt tip portion (e.g., not as sharp as a later formed atomically sharp modified tip portion) in the upper dielectric layer. For example, the blunt tip portion has a width of more than the 1-3 atomic spacings described herein above. As noted herein, there can be various processes for forming the wedge-shaped grooves including utilizing oblique, directional deposition (step 611), utilizing oblique, directional etching (step 612), utilizing oblique, directional modification of material and molding (step 613), or utilizing a combination of directional and isotropic etching (step 614).

Following groove formation, in step 603, the groove walls are lined with a hexagonal polycrystalline or 2D material, which results in the modified tip portion that is atomically sharp (e.g., about 1-3 atomic spacings). In step 604, amorphous group-IV semiconductor material is deposited in the grooves. In step 605, using, for example, an annealing process, the amorphous group-IV semiconductor material is liquified (melted) and crystallized. In step 606, excess group-IV semiconductor material is removed to form oriented single-crystalline semiconductor seed structures.

In step 607, active areas for semiconductor devices are formed and patterned from the seed structures, and in step 608, semiconductor devices (e.g., different types of FETs described herein above) are formed over the seed structures.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming oriented crystal seed structures in semiconductor device dielectric layers. With conventional approaches, transistor performance is negatively affected by defects in a crystalline matrix and by randomly oriented crystalline patches in crystal semiconductor materials. Current techniques such as bonding a thick single crystalline semiconducting layer to BEOL structures require removal of excess semiconductor material, and are limited to one extra bonded layer. The illustrative embodiments advantageously satisfy a need to obtain crystals with single orientations irrespective of substrate-based seeds or bonding layers, and to form single crystalline patches with fixed, but different orientations tailored for different semiconductor devices (e.g., nFET vs. pFET).

The embodiments advantageously use wedge-shaped grooves with confining walls having atoms arranged in hexagonal symmetry to act as templates for crystallization of seed structures. The presence of hexagonal arrangements at the tip of a groove acts as a template for further crystal growth. The use of grooves with atomically sharp V-shaped tips advantageously generates selectively oriented single crystals for group-IV semiconductor materials. The resulting crystalline seed structures and their orientation can be independent from the crystallinity of the semiconductor substrate.

In one embodiment, a semiconductor device includes a dielectric layer including at least one wedge-shaped seed structure. The at least one wedge-shaped seed structure includes semiconductor crystalline material.

The at least one wedge-shaped seed structure may include a first wall and a second wall opposite the first wall, wherein an angle between the first wall and the second wall is in a range of one of about 40 degrees to about 55 degrees and about 65 degrees to about 73 degrees. The at least one wedge-shaped seed structure may include a first wall, a second wall, and a tip portion at a base of the at least one wedge-shaped seed structure. A sharpness of the tip portion can be in a range of about 1 atomic spacing to about 3 atomic spacings of the semiconductor crystalline material. The semiconductor crystalline material may include at least one group-IV semiconductor.

The at least one wedge-shaped seed structure may include a first plane and a second plane perpendicular to the first plane, wherein the first plane has a (100) crystal orientation, and the second plane has a (110) crystal orientation. The first plane may be parallel to a top surface of the at least one wedge-shaped seed structure, and the second plane may be perpendicular to the top surface of the at least one wedge-shaped seed structure. At least one transistor may be disposed over the at least one wedge-shaped seed structure, wherein source-to-drain (S-D), transistor current flow for the at least one transistor is along one of the first plane and the second plane.

The at least one wedge-shaped seed structure may include a first wall and a second wall opposite the first wall, wherein the first wall and the second wall each include a crystalline film layer with hexagonal symmetry. The crystalline film layer on the first wall and on the second wall can include one of graphene, hexagonal boron nitride (h-BN), and a metal-chalcogen. The crystalline film layer on the first wall and on the second wall may include one of a polycrystalline nitride and a polycrystalline oxide. The crystalline film layer on the first wall may have a first orientation and the crystalline film layer on the second wall may have a second orientation. The semiconductor crystalline material may be a single crystal.

In another embodiment, a semiconductor device includes a plurality of seed structures disposed in a dielectric layer. The plurality of seed structures are spaced apart from each other. Respective ones of the plurality of seed structures have a tapered shape with a decreasing width from an upper surface of the dielectric layer, and include semiconductor crystalline material.

The respective ones of the plurality of seed structures may include a first wall and a second wall opposite the first wall, wherein an angle between the first wall and the second wall is in a range of one of about 40 degrees to about 75 degrees. The respective ones of the plurality of seed structures can include a first plane and a second plane perpendicular to the first plane, wherein the first plane has a (100) crystal orientation, and the second plane has a (110) crystal orientation. The respective ones of the plurality of seed structures may include a first wall and a second wall opposite the first wall, wherein the first wall and the second wall each include a crystalline film layer with hexagonal symmetry.

In another embodiment, a semiconductor device includes a dielectric layer including a plurality of wedge-shaped grooves, wherein respective ones of the plurality of wedge-shaped grooves include respective ones of a plurality of seed structures disposed therein, the respective ones of the plurality of seed structures including a crystalline material. A plurality of transistors are disposed over the plurality of wedge-shaped grooves including the respective ones of the plurality of seed structures disposed therein.

The respective ones of the plurality of seed structures may include a first plane and a second plane perpendicular to the first plane, and wherein the first plane has a (100) crystal orientation, and the second plane has a (110) crystal orientation. The respective ones of the plurality of wedge-shaped grooves may include a first wall and a second wall opposite the first wall, wherein the first wall and the second wall each include a crystalline film layer with hexagonal symmetry.

In another embodiment, a semiconductor device includes a first seed structure disposed in a dielectric layer, a second seed structure disposed in the dielectric layer adjacent the first seed structure, a first field-effect transistor (FET) disposed on the first seed structure; and a second FET disposed on the second seed structure. The first seed structure and the second seed structure each have a tapered shape with a decreasing width in a direction away from the first FET and the second FET. The first seed structure and the second seed structure each include semiconductor crystalline material.

The first seed structure and the second seed structure each may include a first plane and a second plane perpendicular to the first plane, wherein the first plane has a (100) crystal orientation, and the second plane has a (110) crystal orientation. Source-to-drain, transistor current flow for the first field-effect transistor and for the second field-effect transistor can be along one of the first plane and the second plane.

In another embodiment, a method for manufacturing a semiconductor device includes forming a plurality of wedge-shaped grooves in a dielectric layer, lining sides of respective ones of the plurality of wedge-shaped grooves with a crystalline film material having hexagonal symmetry, depositing amorphous semiconductor material in the respective ones of the plurality of wedge-shaped grooves, and melting and crystallizing the amorphous semiconductor material to form respective ones of a plurality seed structures in the respective ones of the plurality of wedge-shaped grooves. The respective ones of the plurality of seed structures include semiconductor crystalline material.

The melting and crystallizing can be performed using an annealing process, wherein the annealing process for less than 1 second. The respective ones of the plurality of seed structures may include a first plane and a second plane perpendicular to the first plane, and wherein the first plane has a (100) crystal orientation, and the second plane has a (110) crystal orientation.

It should be understood that the various layers, structures, and regions shown in the figures are schematic illustrations that are not drawn to scale. In addition, for case of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a dielectric layer comprising at least one wedge-shaped seed structure;
wherein the at least one wedge-shaped seed structure comprises semiconductor crystalline material.

2. The semiconductor device of claim 1, wherein the at least one wedge-shaped seed structure comprises a first wall and a second wall opposite the first wall, and wherein an angle between the first wall and the second wall is in a range of one of about 40 degrees to about 55 degrees and about 65 degrees to about 73 degrees.

3. The semiconductor device of claim 1, wherein:
the at least one wedge-shaped seed structure comprises a first wall, a second wall, and a tip portion at a base of the at least one wedge-shaped seed structure; and
a sharpness of the tip portion is in a range of about 1 atomic spacing to about 3 atomic spacings of the semiconductor crystalline material.

4. The semiconductor device of claim 1, wherein the semiconductor crystalline material comprises at least one group-IV semiconductor.

5. The semiconductor device of claim 1, wherein the at least one wedge-shaped seed structure comprises a first plane and a second plane perpendicular to the first plane, and wherein the first plane has a (100) crystal orientation, and the second plane has a (110) crystal orientation.

6. The semiconductor device of claim 5, wherein the first plane is parallel to a top surface of the at least one wedge-shaped seed structure, and the second plane is perpendicular to the top surface of the at least one wedge-shaped seed structure.

7. The semiconductor device of claim 5, further comprising at least one transistor disposed over the at least one wedge-shaped seed structure, wherein source-to-drain current flow for the at least one transistor is along one of the first plane and the second plane.

8. The semiconductor device of claim 1, wherein the at least one wedge-shaped seed structure comprises a first wall and a second wall opposite the first wall, and wherein the first wall and the second wall each comprise a crystalline film layer with hexagonal symmetry.

9. The semiconductor device of claim 8, wherein the crystalline film layer on the first wall and on the second wall comprises one of graphene, hexagonal boron nitride (h-BN), and a metal-chalcogen.

10. The semiconductor device of claim 8, wherein the crystalline film layer on the first wall and on the second wall comprises one of a polycrystalline nitride and a polycrystalline oxide.

11. The semiconductor device of claim 8, wherein the crystalline film layer on the first wall has a first orientation and the crystalline film layer on the second wall has a second orientation.

12. The semiconductor device of claim 1, wherein the semiconductor crystalline material is a single crystal.

13. A semiconductor device comprising:
a plurality of seed structures disposed in a dielectric layer;
wherein the plurality of seed structures are spaced apart from each other;
wherein respective ones of the plurality of seed structures have a tapered shape with a decreasing width from an upper surface of the dielectric layer; and
wherein the respective ones of the plurality of seed structures comprise semiconductor crystalline material.

14. The semiconductor device of claim 13, wherein the respective ones of the plurality of seed structures comprise a first wall and a second wall opposite the first wall, and wherein an angle between the first wall and the second wall is in a range of one of about 40 degrees to about 75 degrees.

15. The semiconductor device of claim 13, wherein the respective ones of the plurality of seed structures comprise a first plane and a second plane perpendicular to the first plane, and wherein the first plane has a (100) crystal orientation, and the second plane has a (110) crystal orientation.

16. The semiconductor device of claim 13, wherein the respective ones of the plurality of seed structures comprise a first wall and a second wall opposite the first wall, and wherein the first wall and the second wall each comprise a crystalline film layer with hexagonal symmetry.

17. A semiconductor device comprising:
a dielectric layer comprising a plurality of wedge-shaped grooves, wherein respective ones of the plurality of wedge-shaped grooves include respective ones of a plurality of seed structures disposed therein, the respective ones of the plurality of seed structures comprising a crystalline material; and
a plurality of transistors disposed over the plurality of wedge-shaped grooves including the respective ones of the plurality of seed structures disposed therein.

18. The semiconductor device of claim 17, wherein the respective ones of the plurality of seed structures comprise a first plane and a second plane perpendicular to the first plane, and wherein the first plane has a (100) crystal orientation, and the second plane has a (110) crystal orientation.

19. The semiconductor device of claim 17, wherein the respective ones of the plurality of wedge-shaped grooves comprise a first wall and a second wall opposite the first wall, and wherein the first wall and the second wall each comprise a crystalline film layer with hexagonal symmetry.

20. A semiconductor device comprising:
a first seed structure disposed in a dielectric layer;
a second seed structure disposed in the dielectric layer adjacent the first seed structure;
a first field-effect transistor disposed on the first seed structure; and
a second field-effect transistor disposed on the second seed structure;
wherein the first seed structure and the second seed structure each have a tapered shape with a decreasing width in a direction away from the first field-effect transistor and the second field-effect transistor; and
wherein the first seed structure and the second seed structure each comprise semiconductor crystalline material.

21. The semiconductor device of claim 20, wherein the first seed structure and the second seed structure each comprise a first plane and a second plane perpendicular to the first plane, and wherein the first plane has a (100) crystal orientation, and the second plane has a (110) crystal orientation.

22. The semiconductor device of claim 21, wherein source-to-drain current flow for the first field-effect transistor and for the second field-effect transistor is along one of the first plane and the second plane.

23. A method for manufacturing a semiconductor device, comprising:
forming a plurality of wedge-shaped grooves in a dielectric layer;
lining sides of respective ones of the plurality of wedge-shaped grooves with a crystalline film material having hexagonal symmetry;
depositing amorphous semiconductor material in the respective ones of the plurality of wedge-shaped grooves; and
melting and crystallizing the amorphous semiconductor material to form respective ones of a plurality seed structures in the respective ones of the plurality of wedge-shaped grooves, the respective ones of the plurality of seed structures comprising semiconductor crystalline material.

24. The method of claim 23, wherein the melting and crystallizing is performed using an annealing process, wherein the annealing process is performed for less than 1 microsecond.

25. The method of claim 23, wherein the respective ones of the plurality of seed structures comprise a first plane and a second plane perpendicular to the first plane, and wherein the first plane has a (100) crystal orientation, and the second plane has a (110) crystal orientation.
